(19) United States
(12) Patent Application Publication
(10) Pub. No.: US 2025/0038679 A1
(43) Pub. Date: Jan. 30, 2025

(54) LOAD DRIVING DEVICE

(71) Applicant: DENSO CORPORATION, Kariya-city (JP)

(72) Inventor: HIROKAZU KAWASAKI, Kariya-city (JP)

(21) Appl. No.: 18/919,233

(22) Filed: Oct. 17, 2024

Related U.S. Application Data
(63) Continuation of application No. PCT/JP2023/014542, filed on Apr. 10, 2023.

(30) Foreign Application Priority Data
Apr. 20, 2022 (JP) 2022-069517

(51) Int. Cl. H02M 7/5387; H02H 11/00; H02M 1/32

(52) U.S. Cl. CPC H02M 7/53871; H02H 11/003; H02M 1/32

(57) ABSTRACT

A power converter is provided between a power supply line connected to the battery and a ground line and converts a direct current power of the battery and supplies it to a load. A control circuit controls an operation of the power converter. A reverse connection protection relay is provided on the ground line and, when turned off, cuts off the current flowing from the ground line through the power converter to the power supply line when the battery is reverse connected. The reverse connection protection relay is a transistor having a parasitic diode that conducts current from source to drain. The control circuit detects an abnormality in the reverse connection protection relay based on a monitor voltage corresponding to a voltage drop from the source to the drain of the reverse connection protection relay and a voltage drop of the parasitic diode.

### CROSS REFERENCE TO RELATED APPLICATIONS

This application is a continuation application of International Patent Application No. PCT/JP2023/014542 filed on Apr. 10, 2023, which designated the U.S. and based on and claims the benefits of priority of Japanese Patent Application No. 2022-069517 filed on Apr. 20, 2022. The entire disclosure of all of the above applications is incorporated herein by reference.

### TECHNICAL FIELD

The present disclosure relates to a load driving device.

### BACKGROUND

Conventionally, a technique for detecting an abnormality in a reverse connection protection relay in a load driving device that converts DC power from a battery using a power converter such as an inverter and supplies the converted power to a load is known.

### SUMMARY

An object of the present disclosure is to provide a load driving device capable of detecting an abnormality in a reverse connection protection relay provided in a ground line.

A load driving device according to the present disclosure includes a power converter, a control circuit, and a reverse connection protection relay. The power converter is provided between a power supply line connected to a battery and a ground line, and converts a direct-current (DC) power from the battery and supplies it to a load. The control circuit controls an operation of the power converter.

The reverse connection protection relay is provided on the ground line, and when turned off, cuts off the current that flows from the ground line through the power converter to the power supply line when the battery is connected in reverse.

The reverse connection protection relay is configured with a transistor whose drain is connected to a battery side of the ground line and whose source is connected to a power converter side, and which has a parasitic diode that conducts current from the source to the drain. The control circuit detects an abnormality in the reverse connection protection relay based on a monitor voltage equivalent to a voltage drop from the source to the drain of the reverse connection protection relay and a voltage drop in the parasitic diode.

### BRIEF DESCRIPTION OF THE DRAWINGS

The above and other objects, features and advantages of the present disclosure will become more apparent from the following detailed description taken in conjunction with the accompanying drawings. In the drawings:

FIG. 1 is a configuration diagram of a motor drive device according to a first embodiment;

FIG. 2 is a configuration diagram of a control circuit according to a first embodiment;

FIG. 3 is a flowchart of an abnormality detection for a reverse connection protection relay in an initial check;

FIG. 4 is a flow chart of an abnormality detection for the reverse connection protection relay during normal operation;

FIG. 5 is a configuration diagram of a motor drive device according to a second embodiment;

FIG. 6 is a configuration diagram of a control circuit according to a second embodiment; and

FIG. 7 is a configuration diagram of a motor drive device according to a third embodiment.

### DETAILED DESCRIPTION

In an assumable example, a technique for detecting an abnormality in a reverse connection protection relay in a load driving device that converts DC power from a battery using a power converter such as an inverter and supplies the converted power to a load is known. For example, in a motor drive device, a power supply relay (first FET) on the battery side and a reverse connection protection relay (second FET) on the inverter side are connected in series to a power supply line between the battery and the inverter. An electrode on a high potential side of a capacitor is connected between the reverse connection protection relay and the inverter.

During an initial check, a control unit detects a short circuit failure or an open circuit failure of the power relay and the reverse connection protection relay based on a voltage at point P1 between the power supply relay and the reverse connection protection relay, and a voltage at point P2 between the reverse connection protection relay and the inverter, when a voltage is charged to the electrode on the high potential side of the capacitor.

A load driving device such as an auxiliary motor adapted to a vehicle may be designed with a 12-volt battery. In the future, an auxiliary battery voltage for an electric vehicle may be expected to be increased to 24 volts or 48 volts, which exceeds the voltage tolerance of the conventional 12-volt drive circuit. For example, when a reverse connection protection relay constituted by an N-channel MOSFET is provided on a power supply line, a driver capable of applying a high voltage, which is the sum of the battery voltage and the gate drive voltage, to the gate is required.

Therefore, by providing a reverse connection protection relay on the ground line, it becomes possible to drive the gate at a low voltage. Therefore, a high voltage driver is not required. However, the conventional technology intended for a configuration in which a power supply relay and a reverse connection protection relay are connected in series in a power supply line, and cannot be applied to an abnormality detection of a reverse connection protection relay provided independently in a ground line.

An object of the present disclosure is to provide a load driving device capable of detecting an abnormality in a reverse connection protection relay provided in a ground line.

A load driving device according to the present disclosure includes a power converter, a control circuit, and a reverse connection protection relay. The power converter is provided between a power supply line connected to a battery and a ground line, and converts a direct-current (DC) power from the battery and supplies it to a load. The control circuit controls an operation of the power converter.

The reverse connection protection relay is provided on the ground line, and when turned off, cuts off the current that flows from the ground line through the power converter to the power supply line when the battery is connected in reverse.

The reverse connection protection relay is configured with a transistor whose drain is connected to a battery side of the ground line and whose source is connected to a power converter side, and which has a parasitic diode that conducts current from the source to the drain. The control circuit detects an abnormality in the reverse connection protection relay based on a monitor voltage equivalent to a voltage drop from the source to the drain of the reverse connection protection relay and a voltage drop in the parasitic diode.

In the present disclosure, for example, in a drive circuit to which a battery voltage of 24V or 48V is applied, it is possible to detect an abnormality in the reverse connection protection relay provided in the ground line. For example, by detecting an abnormality in the reverse connection protection relay during an initial check after starting up the load driving device, measures to deal with the abnormality can be taken early, improving reliability.

A load driving device according to a plurality of embodiments will be described based on the drawings. In the multiple embodiments, substantially the same components are denoted by the same reference numerals, and a description of the same components will be omitted. The following first to third embodiments are collectively referred to as “present embodiment.” The load driving device of the present embodiment is a motor drive device. This motor drive device converts the direct-current (DC) power from a battery in an electric power steering device and supplies it to a steering assist motor as a “load.” The steering assist motor is configured by a three-phase brushless motor.

Although the voltage of an auxiliary battery mounted on a vehicle has conventionally been generally 12V, in the present embodiment, it is mainly assumed that the voltage is 24V or 48V, which is expected to be adopted in electric vehicles in the future. “24V/48V” in the figures and the following specification means “24V or 48V.” However, even when using a 12V battery, the configuration according to the present embodiment is basically the same. As it is obvious from the use of the term “IG (ignition),” the present embodiment may be applied not only to electric vehicles but also to engine vehicles.

Specifically, the ECU of the electric power steering device functions as a motor drive device. The ECU is configured by a microcomputer, a customized ASIC, etc., and includes a CPU, a ROM, a RAM, an I/O, and a bus line (not shown) connecting these components. The ECU performs required control by executing software processing or hardware processing. The software processing may be implemented by causing the CPU to execute a program. The program may be stored beforehand in a memory device such as a ROM, that is, in a readable non-transitory tangible storage medium. The hardware processing may be implemented by a special purpose electronic circuit.

### First Embodiment

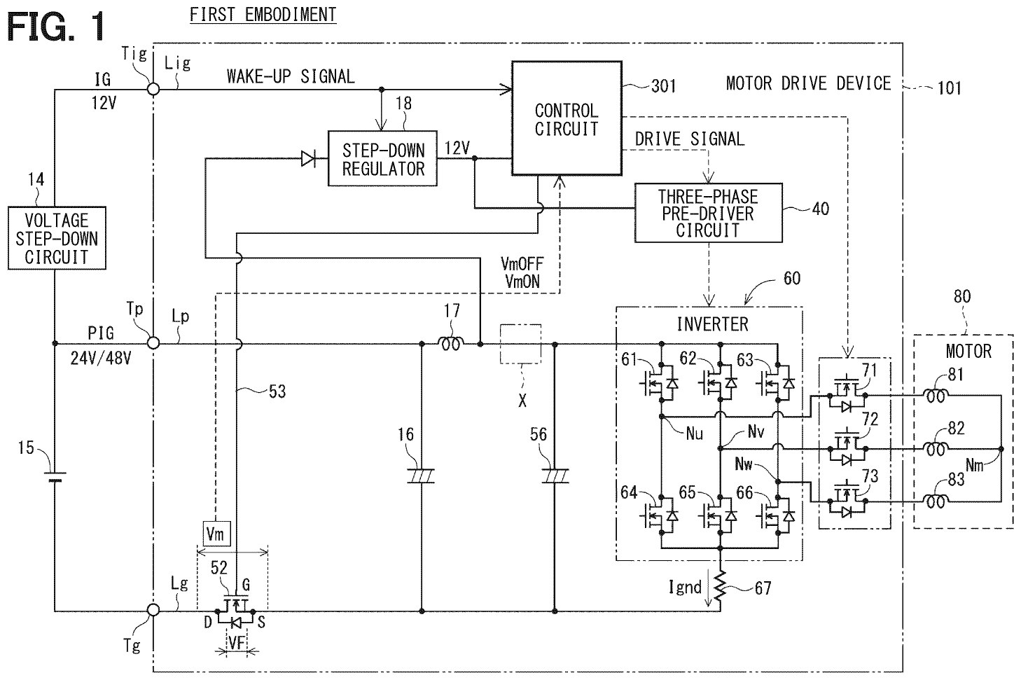

The reference numeral for the motor drive device of each embodiment is denoted by the number of the embodiment as the third digit following “10”. A motor drive device 101 according to a first embodiment will be described with reference to FIGS. 1 to 4. In the following, a battery 15 being connected in a normal direction may also be referred to as a forward connection; and the battery 15 being connected in a direction being opposite to the normal direction may also be referred to as a reverse connection. As shown in FIG. 1, in the forward connection state, the positive electrode of the battery 15 is connected to the power terminal Tp of the motor drive device 101; and the negative electrode of the battery 15 is connected to the ground terminal Tg of the motor drive device 101. A positive electrode of the battery 15 is connected to the IG terminal Tig of the motor drive device 101 via a voltage step-down circuit 14.

Wirings connected to a power supply terminal Tp, a ground terminal Tg, and an IG terminal Tig are respectively referred to as a power supply line Lp, a ground line Lg, and an IG line Lig. The voltage applied to the power supply line Lp is referred to as a PIG voltage, and the voltage applied to the IG line Lig is referred to as an IG voltage. In the present embodiment, the PIG voltage is 24V or 48V, and the IG voltage is 12V. A wake-up signal is transmitted via the IG line Lig.

The motor drive device 101 includes an inverter 60 as a “power converter”, a reverse connection protection relay 52, a step-down regulator 18, a control circuit 301, and the like. Although FIG. 1 illustrates the configuration of one system of motor drive device 101, a redundant configuration of two or more systems of motor drive device 101 may be used. For example, in the two systems of motor drive device, power is supplied from two inverters to a double-winding motor having two sets of windings.

The inverter 60 is provided between the power supply line Lp and the ground line Lg. The power supply line Lp is connected to a positive electrode of a battery 15 in the forward connection state. The ground line Lg is connected to a negative electrode of the battery 15 in the forward connection state. The inverter 60 includes three sets of upper and lower arm switching elements 61 to 66, which are connected in series between the power supply line Lp and the ground line Lg. The upper arm switching elements 61, 62, and 63 of the U phase, V phase, and W phase and the lower arm switching elements 64, 65, and 66 of the U phase, V phase, and W phase are connected in a bridge configuration. In the present embodiment, MOSFETs are used as the switching elements 61 to 66 of the inverters 60. In the present embodiment, the MOSFET is an n-channel type.

Inter-arm connection points Nu, Nv, and Nw are connected to three-phase windings 81, 82, and 83 of the motor 80, respectively. The inter-arm connection points Nu, Nv, Nw are connection nodes between corresponding two of the switching elements 61 to 66 in the upper arm and the lower arm of respective phases of the inverter 60. The inverter 60 converts DC power of the battery 15 and then supplies the converted power to the three-phase windings 81, 82, 83. For example, when the motor 80 is in a Y-connection, the three-phase windings 81, 82, 83 are connected at a neutral point Nm. However, the three-phase windings 81, 82, and 83 may also be in delta connection.

The motor relays 71, 72, 73 are provided in a motor current path between the inter-arm connection points Nu, Nv, Nw of corresponding phases and the phase windings 81, 82, 83, respectively. The motor relays 71, 72, 73 are MOSFETs, and have the parasitic diodes that allow current to flow from the inter-arm connection points Nu, Nv, Nw to the phase windings 81, 82, 83, respectively. The motor relays 71, 72, 73 cut off current from the motor 80 side to the inverter 60 side when the motor relays are in the off state.

A shunt resistor 67 is provided on the ground line Lg side of the inverter 60. In at least the second embodiment, the shunt resistor 67 is used as a means for detecting the ground current Ignd flowing through the ground line Lg. However, in a configuration in which the current of each phase is detected in the current feedback control of the inverter 60, the three shunt resistors provided on the ground line Lg side of the lower arm of each phase may also be used as current sensors for detecting the ground current Ignd.

An inverter capacitor 56 is connected in parallel with inverter 60 between the power supply line Lp and the ground line Lg. The inverter capacitor 56 is an electrolytic capacitor, and is charged with energy supplied to the inverter 60 from the power supply line Lp. During normal operation of the motor drive device 101, the inverter capacitor 56 functions as a smoothing capacitor.

A filter capacitor 16 and a choke coil (inductor) 17 are provided on the battery 15 side of the inverter 60. The filter capacitor 16 and the choke coil 17 are included in an LC filter circuit adopted for a power supply filter. The choke coil 17 is provided on the power supply line Lp. The LC filter circuit is not limited to the L-type, which includes one filter capacitor 16 and one choke coil 17, as shown in the drawing, but may also be the TT-type or the T-type. The TT-type includes two filter capacitors 16. The T-type includes two choke coils 17.

Typically, the filter capacitor 16 is a polar electrolytic capacitor such as an aluminum electrolytic capacitor, and forms an LC filter circuit with the choke coil 17. The polar electrolytic capacitor has a lower negative bias withstand capability than a positive bias withstand capability. Therefore, if a negative bias voltage is applied when the battery 15 is reversely connected, the aluminum electrolytic capacitor may be destroyed (exploded).

If the battery 15 is reversely connected, a current flows from the ground line Lg to the power line Lp via the inverter 60 unless the current path is interrupted. Even though the switching elements 61 to 66 of the inverter 60 are in the off state, the current flows via the parasitic diode. The reverse connection protection relay 52 cuts off this current when in the off state.

In the present embodiment, the reverse connection protection relay 52 is provided in the ground line Lg. More specifically, the reverse connection protection relay 52 is provided on the ground line Lg closer to the battery 15 than the negative electrode of the filter capacitor 16. The reverse connection protection relay 52 has a drain connected to the battery 15 side of the ground line Lg, and a source connected to the inverter 60 side.

The reverse connection protection relay 52 is a transistor having a “parasitic diode that conducts current from the source to the drain.” Specifically, the reverse connection protection relay 52 in the present embodiment is configured with a MOSFET. In the figure, “D” represents a drain, “S” represents a source, and “G” represents a gate. The voltage equivalent to the voltage drop from the source to the drain is defined as “monitor voltage Vm.”

The parasitic diode of the reverse connection protection relay 52 conducts the ground current Ignd from the inverter 60 side to the battery 15 side in the ground line Lg. The voltage drop of the parasitic diode when the ground current Ignd is conducted is represented as “VF.” The monitor voltage Vm and the voltage drop VF of the parasitic diode are defined as positive values.

A gate voltage is supplied to the gate of the reverse connection protective relay 52 via a gate voltage supply path 53. In other words, a gate signal is input to the gate of the reverse connection protective relay 52. In the present embodiment, the reverse connection protection relay 52 is driven by a gate signal from the control circuit 301. For example, a voltage of about 5V generated by the control circuit 301 is supplied to the gate of the reverse connection protection relay 52. When the battery 15 is reversely connected, the control circuit 301 does not operate and no gate signal is supplied. Thus, the reverse connection protective relay 52 is not turned on.

In the present embodiment, a circuit configuration is assumed in which basically no power relay is provided. The power supply relay may be located at a position X of the power supply line Lp indicated by a two-dotted chain line. In other words, the power supply relay may be provided between the choke coil 17 and the inverter 60. In this situation, the parasitic diode of the MOSFET included in the reverse-connection protective relay 52 conducts a current from the inverter 60 side to the battery 15 side. The power supply relay interrupts the current flowing from the battery 15 side to the inverter 60 side at the off state, when the battery 15 is in the forward connection.

The step-down regulator 18 steps down the PIG voltage of 24V/48V supplied from the power supply line Lp subsequent to the choke coil 17 to 12V, and outputs the voltage to the control circuit 301 and a three-phase pre-driver circuit 40. When the motor drive device 101 is started up, a wake-up signal is input from the IG line Lig to the step-down regulator 18 and the control circuit 301.

The control circuit 301 includes a microcomputer, an ASIC, and the like, and operates on the voltage supplied from the battery 15, and controls the operation of the inverter 60 via the three-phase pre-driver circuit 40. During the normal operation of the motor drive device 101, the control circuit 301 calculates a drive signal for the inverter 60 by current feedback control based on the phase current detection value and the motor rotation angle so that the motor 80 outputs the command torque. In the case of a dual-system configuration, control information may be mutually communicated between the respective microcomputers of individual systems. The three-phase pre-driver circuit 40 drives the switching elements 61 to 66 of the inverter 60 based on the drive signal calculated by the control circuit 301.

In addition, the control circuit 301 outputs an ON/OFF signal to the reverse connection protection relay 52 and the motor relays 71, 72, and 73. Furthermore, during the initial check and normal operation, the control circuit 301 detects an abnormality such as a stuck-on abnormality or a stuck-off abnormality of the reverse connection protection relay 52 based on the monitor voltage Vm of the reverse connection protection relay 52.

For example, a conventional technique is disclosed, which detects a short circuit failure or an open circuit failure in a power supply relay and a reverse connection protection relay connected in series to a power supply line Lp. However, this conventional technique cannot be applied to detecting an abnormality in the reverse connection protection relay 52 that is provided independently in the ground line Lg. Therefore, an object of the present embodiment is to detect an abnormality in the reverse connection protection relay 52 provided in the ground line Lg.

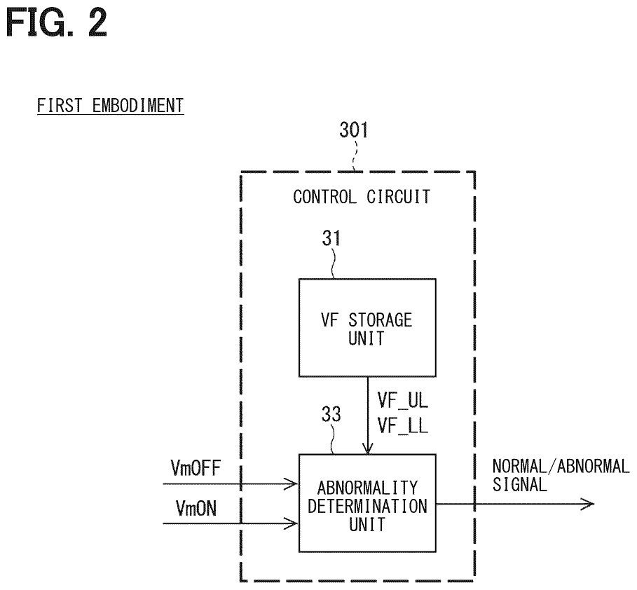

As shown in FIG. 2, the control circuit 301 of the first embodiment includes a VF storage unit 31 and an abnormality determination unit 33. The VF storage unit 31 stores a range of the voltage drop VF of the parasitic diode as a fixed value. The range of the voltage drop VF of the parasitic diode is determined based on the individual variation of parts and the range of fluctuation in characteristics due to current or temperature changes under initial check conditions. At the time of the initial check, the VF storage unit 31 notifies the abnormality determination unit 33 of an upper limit value VF_UL and a lower limit value VF_LL of the voltage drop of the parasitic diode.

The abnormality determination unit 33 acquires an ON-time monitor voltage VmON, which is the “monitor voltage when the reverse connection protection relay 52 is turned ON”, and an OFF-time monitor voltage VmOFF, which is the “monitor voltage when the reverse connection protection relay is turned OFF”. The abnormality determination unit 33 determines an abnormality in the reverse connection protection relay 52 based on the ON-time monitor voltage VmON and the OFF-time monitor voltage VmOFF and the voltage drop VF of the parasitic diode, and outputs a normal signal or an abnormal signal.

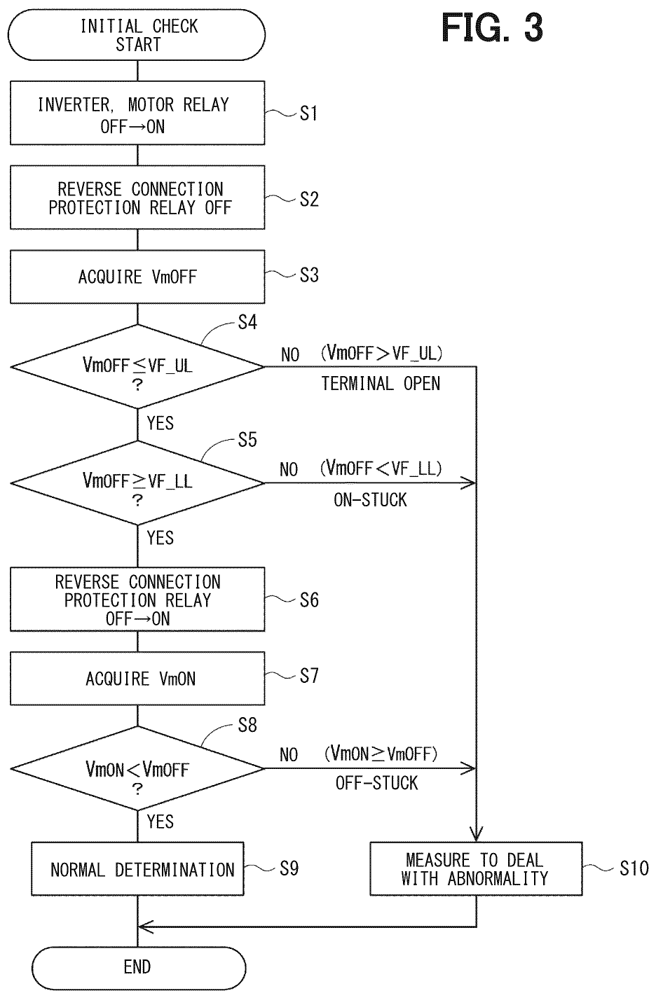

Next, the detection of the abnormality in the reverse connection protection relay 52 during the initial check after the start-up of the motor drive device 101 will be described with reference to the flowchart of FIG. 3. In the following flowchart, a symbol S indicates a step. In S1, the control circuit 301 switches the inverter 60 and the motor relays 71, 72, and 73 from an OFF state to an ON state. By driving the inverter 60 in a predetermined pattern, current flows from the power supply line Lp through the three-phase windings 81, 82, and 83 to the ground line Lg.

The control circuit 301 turns off the reverse connection protection relay 52 in S2, and acquires the OFF-time monitor voltage VmOFF in S3.

In S4, it is determined whether the OFF-time monitor voltage VmOFF is equal to or less than the upper limit VF_UL of the voltage drop of the parasitic diode. In case of YES in S4, the process proceeds to S5. When the result in S4 is NO, that is, when the OFF-time monitor voltage VmOFF is greater than the upper limit value VF_UL of the voltage drop of the parasitic diode, the control circuit 301 determines that the reverse connection protection relay 52 has a terminal open abnormality. The terminal open abnormality is an abnormality in which at least one of the source and drain terminals of the reverse connection protection relay 52 is isolated from the ground line Lg, and corresponds to a terminal disconnection or a poor contact.

In S5, it is determined whether the OFF-time monitor voltage VmOFF is equal to or greater than the lower limit VF_LL of the voltage drop of the parasitic diode. In case of YES in S5, the process proceeds to S6. When the result in S5 is NO, that is, when the OFF-time monitor voltage VmOFF is smaller than the lower limit value VF_LL of the voltage drop of the parasitic diode, the control circuit 301 determines that the reverse connection protection relay 52 has an ON-stuck abnormality.

The control circuit 301 turns the reverse connection protection relay 52 from OFF to ON in S6, and acquires the ON-time monitor voltage VmON in S7.

In S8, it is determined whether the ON-time monitor voltage VmON is smaller than the OFF-time monitor voltage VmOFF. When the result of S8 is YES, it is determined that the reverse connection protection relay 52 is normal in S9. When the result in S8 is NO, that is, when the ON-time monitor voltage VmON is equal to or higher than the OFF-time monitor voltage VmOFF, the control circuit 301 determines that the reverse connection protection relay 52 is in an OFF-stuck abnormality.

When the result is NO in any of S4, S5, and S8, measures to deal with the abnormality are executed in S10. For example, the user is notified of the abnormality by a warning display or the like, and the start of normal operation is prohibited depending on the abnormality mode. Alternatively, when an abnormality is detected in only one system of a two-system motor drive device, one-system drive using the normal system may be performed.

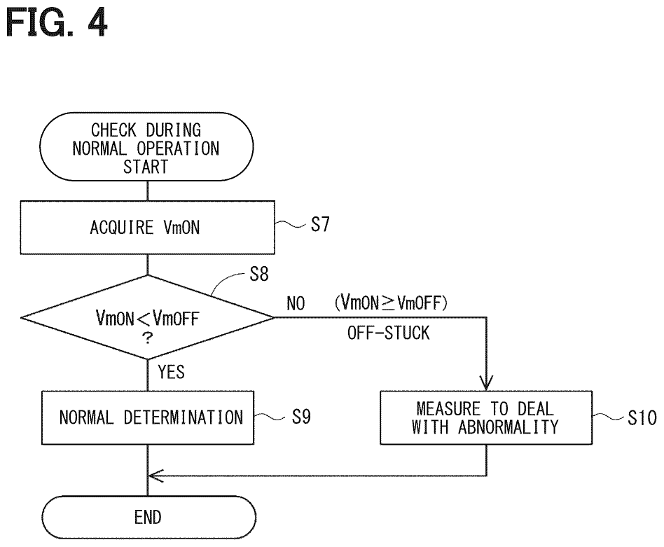

When it is determined to be normal in S9, the process shifts to normal operation. During normal operation, the inverter 60 is energized in a state where the reverse connection protection relay 52 is turned on. The only abnormality mode to be detected during normal operation is a OFF-stuck abnormality that occurs over time. The detection of an abnormality in the reverse connection protection relay 52 during normal operation will be described with reference to the flowchart of FIG. 4. S7 to S10 in the flowchart are the same as those in FIG. 3. Except when the operation is stopped due to measures to deal with the abnormality, the routine of S7 to S10 is repeatedly executed.

The control circuit 301 stores in advance, at the start of normal operation, the OFF-time monitor voltage VmOFF acquired, for example, at the time of an initial check. At the start of normal operation, in S8, the ON-time monitor voltage VmON is lower than the OFF-time monitor voltage VmOFF. During normal operation, when the ON-time monitor voltage VmON becomes equal to or higher than the OFF-time monitor voltage, the result is NO in S8. At this time, the control circuit 301 determines that the reverse connection protection relay 52 is in the OFF-stuck abnormality. In the measures to deal with the abnormality in S10, for example, the motor drive of the system in which the abnormality is detected is stopped.

### Effect of Present Embodiment

### (1) Simplification of Reverse Connection Protective Relay Drive Configuration by Gate Drive at Low Voltage

In the drive circuit to which a battery voltage of 24V/48V is applied, when the reverse connection protection relay composed of an N-channel MOSFET is provided in the power supply line Lp, a driver is required to apply a high voltage, which is the battery voltage plus a gate drive voltage, to the gate. In the present embodiment, since the reverse connection protection relay 52 is provided on the ground line Lg, the gate can be driven at a low voltage, and a high voltage driver is not required.

### (2) Protection of Polar Electrolytic Capacitor or the Like Against Negative Bias Voltage

When the battery 15 is reversely connected, the control circuit 301 does not operate, so that no gate signal is supplied to the reverse connection protection relay 52, and the reverse connection protection relay 52 is in the OFF state. In addition, since the reverse connection protection relay 52 is provided on the battery 15 side with respect to the filter capacitor 16, a negative bias voltage is not applied to the filter capacitor 16 when the reverse connection protection relay 52 is in the OFF state. Thus, the polarized filter capacitor 16 can be protected against negative bias voltages.

### (3) Abnormality Detection of Reverse Connection Protection Relay

In the drive circuit to which a battery voltage of 24V/48V is applied, an abnormality in the reverse connection protection relay 52 provided in the ground line Lg can be detected. For example, by detecting an abnormality in the reverse connection protection relay 52 during an initial check after starting up the motor drive device 101, measures to deal with the abnormality can be taken early, improving reliability.

### Second Embodiment

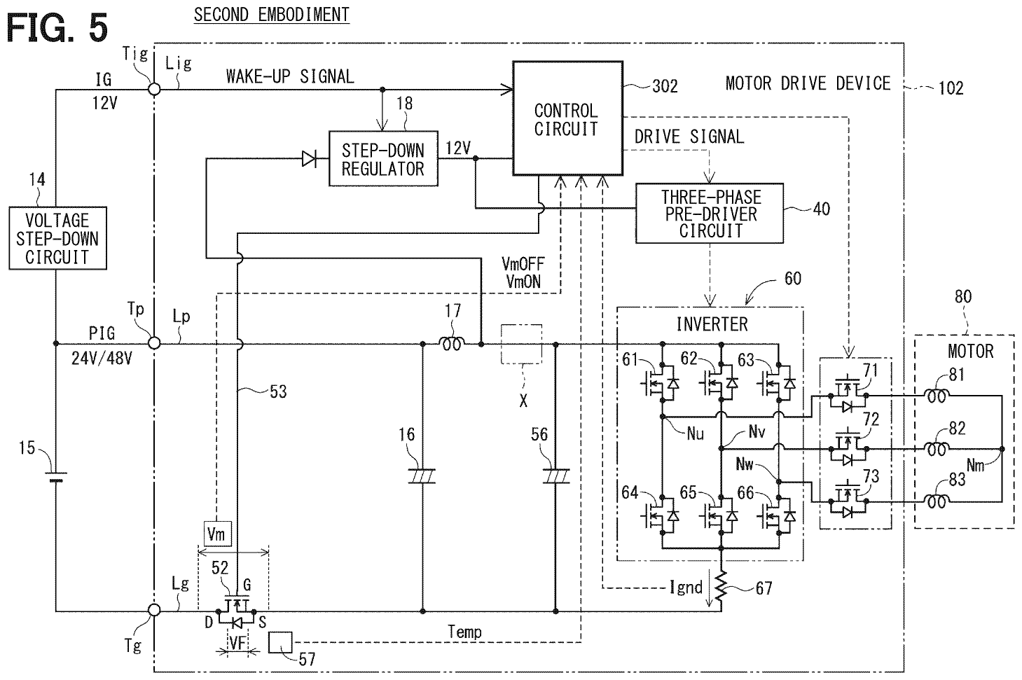

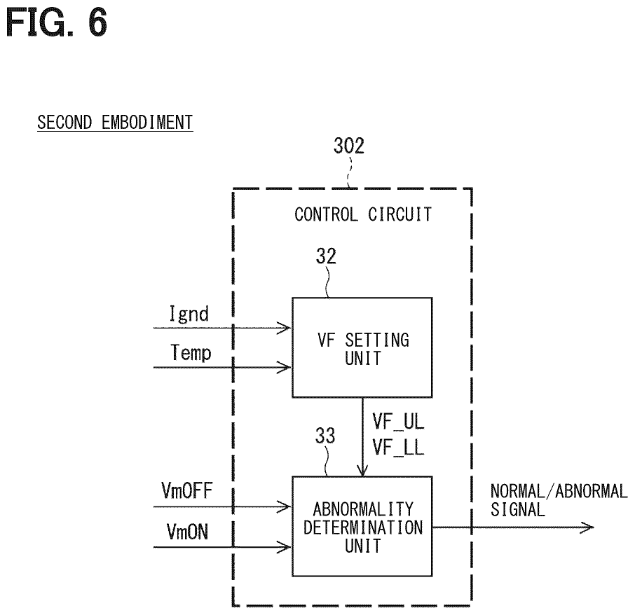

Next, a motor drive device 102 according to a second embodiment will be described with reference to FIGS. 5 and 6. In the second embodiment, the control circuit 302 has, instead of the VF storage unit 31, a VF setting unit 32 that variably sets the range of the voltage drop VF of the parasitic diode in accordance with the current or temperature. The VF setting unit 32 obtains the ground current Ignd from a shunt resistor 67 provided on the ground line Lg side of the inverter 60.

Furthermore, in a circuit configuration in which the temperature sensor 57 is provided in the vicinity of the reverse connection protection relay 52, the VF setting unit 32 may obtain the temperature Temp of the parasitic diode from the temperature sensor 57. Alternatively, the VF setting unit 32 may estimate the temperature Temp of the parasitic diode by adding Joule heat calculated from the ground current Ignd and the resistance of the parasitic diode to the initial temperature before current is applied, which is obtained from an outside air temperature sensor or the like.

The VF setting unit 32 stores the current characteristics and temperature characteristics of the voltage drop VF of the parasitic diode in a map or the like. The VF setting unit 32 sets an upper limit value VF_UL and a lower limit value VF_LL of the voltage drop of the parasitic diode in accordance with the ground current Ignd or the temperature Temp, and notifies the abnormality determination unit 33 of the set values. The abnormality determination unit 33 performs an abnormality detection in an initial check using the notified upper and lower limit values VF_UL, VF_LL.

In a case where the current and temperature conditions during the initial check vary, when the upper and lower limit values VF_UL and VF_LL of the voltage drop of the parasitic diode are set to fixed values, there is a risk of erroneous determination in the detection of an abnormality in the reverse connection protection relay 52. In the second embodiment, the range of the voltage drop VF of the parasitic diode is variably set in accordance with the current or temperature, thereby making it possible to improve the accuracy of abnormality detection.

### Third Embodiment

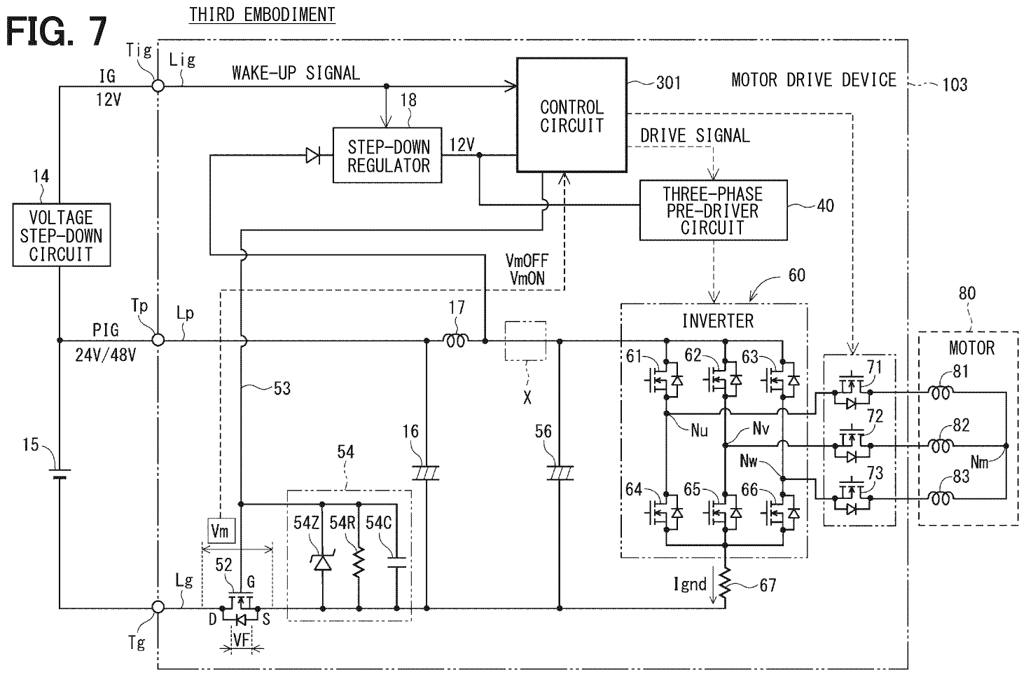

A motor drive device 103 according to a third embodiment will be described with reference to FIG. 7. In the third embodiment, compared to the first embodiment, an OFF-delay circuit 54 in which a Zener diode 54Z, a resistor 54R, and a capacitor 54C are connected in parallel is provided between the gate and source of the reverse connection protection relay 52. When the voltage supplied to the gate decreases, the OFF-delay circuit 54 delays the time until the reverse connection protective relay 52 is turned off by slowing down the rate of decrease in a voltage between the gate and source based on the time constant of RC element.

When a negative surge is applied to the battery voltage while the reverse connection protective relay 52 is in the on state, the energy charged in the inverter capacitor 56 is regenerated into the battery 15. At this time, when the gate-source voltage drops and the reverse connection protection relay 52 is turned off, the drain-source voltage rises and reaches the breakdown voltage of the MOSFET. When this condition continues, it may lead to avalanche destruction.

Therefore, by using the OFF-delay circuit 54 to delay the time until the reverse connection protection relay 52 is turned OFF when a negative surge voltage is applied, it is possible to prevent the drain-source voltage from rising and reaching the breakdown voltage. Therefore, avalanche destruction of the reverse connection protection relay 52 can be prevented.

### Other Embodiments

(a) The “load” of the load driving device is not limited to the three-phase motor 80, but may be a single-phase motor or a multi-phase motor other than three-phase motor, or may be an actuator other than a motor or other load. For example, an H-bridge circuit may be used instead of an inverter as a power converter.

(b) The reverse connection protection relay 52 and the like are not limited to being constituted by MOSFETs, and may be constituted by other transistors having parasitic diodes. In the case of a bipolar transistor, the collector and emitter may be interpreted as the drain and source of a FET.

(c) The reverse connection protection relay 52 is not limited to being driven by a gate signal from the control circuits 301 and 302, and may be driven by a gate voltage supplied from another element via the gate voltage supply path 53. For example, the output voltage of the step-down regulator 18, the IG voltage supplied to the IG line Lig as a wake-up signal, or the PIG voltage supplied to the power supply line Lp from the battery 15 may be supplied to the gate of the reverse connection protection relay 52. The gate voltage supply path 53 may be provided with a diode for preventing a reverse current flow from the gate side, or a resistor for limiting the current flowing through the gate.

(d) As described above, in a circuit that uses a polarized filter capacitor, it is preferable that the reverse connection protection relay 52 be provided on the ground line Lg closer to the battery 15 than the filter capacitor 16. On the other hand, in a circuit using a non-polar filter capacitor that is resistant to negative bias voltage, the reverse connection protection relay 52 may be provided on the ground line Lg closer to the inverter 60 than the filter capacitor 16.

(e) The load driving device according to the present disclosure may be applied to various devices for driving a load including in-vehicle devices other than electric power steering devices and devices other than devices to be mounted on vehicles.

The present disclosure should not be limited to the embodiment described above. Various other embodiments may be implemented without departing from the scope of the present disclosure.

The control circuit and the technique according to the present disclosure may be achieved by a dedicated computer provided by constituting a processor and a memory programmed to execute one or more functions embodied by a computer program. Alternatively, the control circuit and the method described in the present disclosure may be realized by a dedicated computer configured as a processor with one or more dedicated hardware logic circuits. Alternatively, the control circuit and method described in the present disclosure may be realized by one or more dedicated computer, which is configured as a combination of a processor and a memory, which are programmed to perform one or more functions, and a processor which is configured with one or more hardware logic circuits. The computer programs may be stored, as instructions to be executed by a computer, in a tangible non-transitory computer-readable medium.

The present disclosure has been made in accordance with the embodiments. However, the present disclosure is not limited to such embodiments and configurations. The present disclosure also encompasses various modifications and variations within the scope of equivalents. Furthermore, various combination and formation, and other combination and formation including one, more than one or less than one element may be made in the present disclosure.

What is claimed is:

1. A load driving device, comprising:
a power converter provided between a power supply line and a ground line connected to a battery, and configured to convert a direct-current power of the battery and supply it to a load;
a control circuit configured to control an operation of the power converter; and
a reverse connection protection relay that is provided on the ground line and that, when turned off, cuts off a current that flows from the ground line through the power converter to the power supply line when the battery is reversely connected;
wherein
the reverse connection protection relay is configured with a transistor having a drain connected to a battery side of the ground line, a source connected to a power converter side, and a parasitic diode that conducts a current from the source to the drain, and
the control circuit detects an abnormality in the reverse connection protection relay based on a monitor voltage corresponding to a voltage drop from the source to the drain of the reverse connection protection relay and a voltage drop of the parasitic diode.

2. The load driving device according to claim 1, wherein
the control circuit determines, during an initial check after startup of the load driving device, that the reverse connection protection relay is ON-stuck abnormality when an OFF-time monitor voltage, which is a monitor voltage when the reverse connection protection relay is turned OFF, is smaller than a lower limit value of the voltage drop of the parasitic diode.

3. The load driving device according to claim 1, wherein
the control circuit determines, during an initial check after startup of the load driving device, that the reverse connection protection relay is OFF-stuck abnormally when an ON-time monitor voltage, which is a monitor voltage when the reverse connection protection relay is turned ON, is equal to or higher than an OFF-time monitor voltage, which is a monitor voltage when the reverse connection protection relay is turned OFF.

4. The load driving device according to claim 1, wherein
during an initial check after startup of the load driving device, when an OFF-time monitor voltage, which is a monitor voltage when the reverse connection protection relay is turned OFF, is greater than an upper limit value of the voltage drop of the parasitic diode, the control circuit determines that at least one of the source and drain terminals of the reverse connection protection relay is isolated from the ground line, which is a terminal open abnormality.

5. The load driving device according to claim 1, wherein
during normal operation in which current is applied to the power converter in a state where the reverse connection protection relay is turned on,
the control circuit pre-stores an OFF-time monitor voltage, which is a monitor voltage when the reverse connection protection relay is turned OFF, at a start of normal operation, and determines that the reverse connection protection relay has become OFF-stuck abnormality when an ON-time monitor voltage, which is a monitor voltage when the reverse connection protection relay is turned ON, becomes equal to or higher than the OFF-time monitor voltage.

6. A load driving device, comprising:
a power converter provided between a power supply line and a ground line connected to a battery, and configured to convert a direct-current power of the battery and supply it to a load;
a control circuit configured to control an operation of the power converter; and
a reverse connection protection relay that is provided on the ground line and that, when turned off, cuts off a current that flows from the ground line through the power converter to the power supply line when the battery is reversely connected;
wherein
the reverse connection protection relay is configured with a transistor having a drain connected to a battery side of the ground line, a source connected to a power converter side, and a parasitic diode that conducts a current from the source to the drain, and
the control circuit includes a computer having a processor and a memory that stores instructions configured to, when executed by the processor, cause the processor to
detect an abnormality in the reverse connection protection relay based on a monitor voltage corresponding to a voltage drop from the source to the drain of the reverse connection protection relay and a voltage drop of the parasitic diode.
